(19) United States
(12) Patent Application Publication
(10) Pub. No.: US 2013/0168713 A1
(43) Pub. Date: Jul. 4, 2013

(54) LED DEVICE HAVING UNIFORM DISTRIBUTION OF LIGHT INTENSITY OF LIGHT FILED

(71) Applicants: CHAO-HSIUNG CHANG, Hukou (TW); HOU-TE LIN, Hukou (TW)

(72) Inventors: CHAO-HSIUNG CHANG, Hukou (TW); HOU-TE LIN, Hukou (TW)

(73) Assignee: ADVANCED OPTOELECTRONIC TECHNOLOGY, INC., Hsinchu Hsien (TW)

(21) Appl. No.: 13/600,133

(22) Filed: Aug. 30, 2012

(30) Foreign Application Priority Data
Dec. 30, 2011 (CN) 201110453521.9

(51) Int. Cl. H01L 33/58

(52) U.S. Cl. 257/98; 257/E33.074

(57) ABSTRACT

An LED device includes a substrate having a top surface, an LED chip arranged on the top surface of the substrate, an encapsulant arranged on the top surface of the substrate and covering the LED chip, and an optical element arranged over the encapsulant. The optical element includes a light input surface adjacent to the encapsulant and a light output surface opposite to the light input surface. The refractive index of the optical element is larger than that of the encapsulant.

### BACKGROUND

1. Technical Field

The disclosure relates to light emitting diode (LED) devices, and particularly to an LED device with larger light outputting angle and uniform distribution of light intensity of light field.

2. Discussion of Related Art

LED's many advantages, such as high luminosity, low operational voltage, low power consumption, compatibility with integrated circuits, faster switching, long term reliability, and environmental friendliness have promoted their wide use as a lighting source.

However, the conventional LED illumination apparatus generally generates a focused light field which has a light-emitting angle about 120 degrees. A central part of the light filed has much stronger intensity than the other part. This light-emitting angle of the LED illumination apparatus is too small, and the light intensity is too concentrated at the central part of the light filed, which make the LED illumination apparatus not suitable for use in some situations, for example, highway illumination.

Therefore, what is needed is an LED device which can overcome the described limitations.

### BRIEF DESCRIPTION OF THE DRAWINGS

Many aspects of the disclosure can be better understood with reference to the following drawing. The components in the drawing are not necessarily drawn to scale, the emphasis instead being placed upon clearly illustrating the principles of the present LED device for microminiaturization. Moreover, in the drawing, like reference numerals designate corresponding parts throughout the several views.

FIG. 1 is a cross-sectional view of an LED device in accordance with an embodiment of the present disclosure.

FIG. 2 is a top view of the LED device of FIG. 1.

FIG. 3 is a view similar to FIG. 1, added with arrows indicating light paths of the LED device of FIG. 1.

FIG. 4 is a graph illustrating light intensity distribution of light filed of the LED device vs. different illumination angles the LED device of FIG. 1.

### DETAILED DESCRIPTION OF EMBODIMENTS

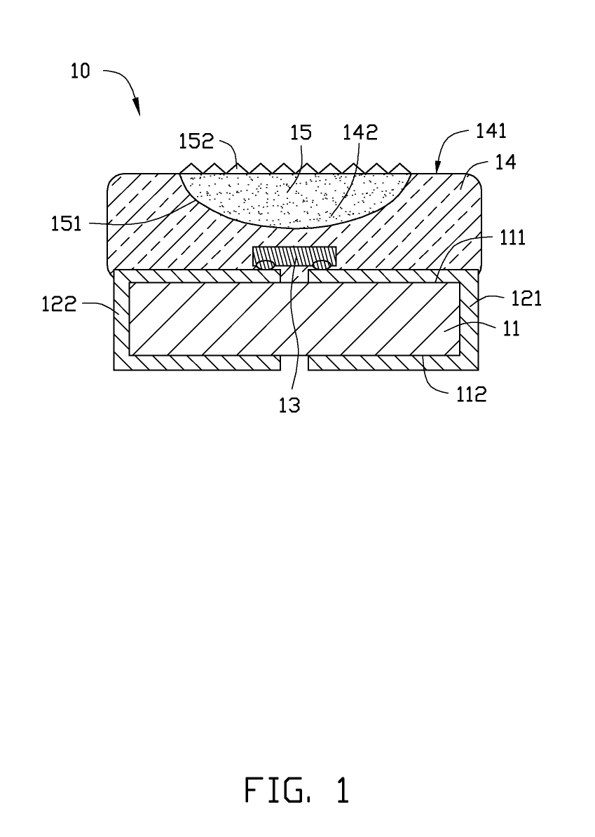

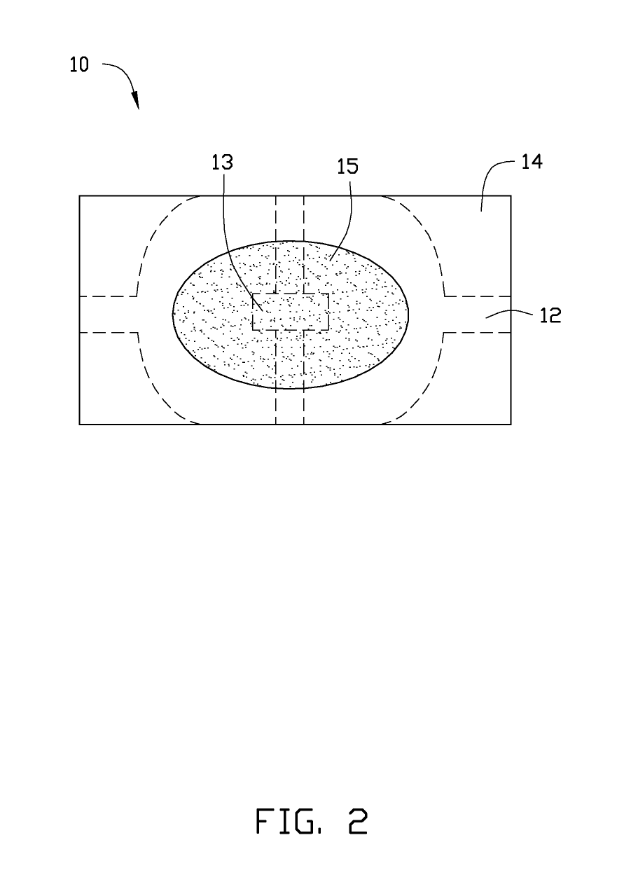

Referring to FIGS. 1 and 2, an LED device 10 in accordance with an exemplary embodiment of the present disclosure is illustrated. The LED device 10 includes a substrate 11, a first electrode 121 and a second electrode 122 respectively formed on two ends of the substrate 11, an LED chip 13 mounted on the first and second electrodes 121, 122, an encapsulant 14 arrange on the light emitting surface of the LED chip 13, and an optical element 15 arranged on the encapsulant 14.

The substrate 11 beneficially is a single rectangular plate and has a planar top surface 111 and a planar bottom surface 112 opposite to and parallel to the top surface 111. In the present embodiment, the substrate 11 is made of electrically insulated material, such as polyphthalamide (PPA).

The first electrode 121 and the second electrode 122 extend from the top surface 111 of the substrate 11 to the bottom surface 112 thereof along an outer edge of the substrate 11. The first electrode 121 and the second electrode 122 can be made of metal with high electrical conductivity selected from a group consisting of gold, silver, copper, platinum, aluminum, nickel, tin, magnesium and an alloy thereof.

The LED chip 13 is mounted on the first and second electrodes 121, 122 via a flip-chip technology. In other embodiments, the LED chip 13 can be mounted on the first electrode 121 or the second electrode 122 and electrically connected thereto via wire bonding.

The encapsulant 14 is arranged on the top surface 111 of the substrate 11 and covers the LED chip 13 and part of the first and second electrodes 121, 122. The encapsulant 14 is formed of solidified silicone, and has a first refractive index n₁ . The encapsulant 14 includes an upper surface 141. In the present embodiment, the upper surface 141 is recessed downwardly to define a concave portion 142 in a center thereof. The concave portion 142 is located over the LED chip 13.

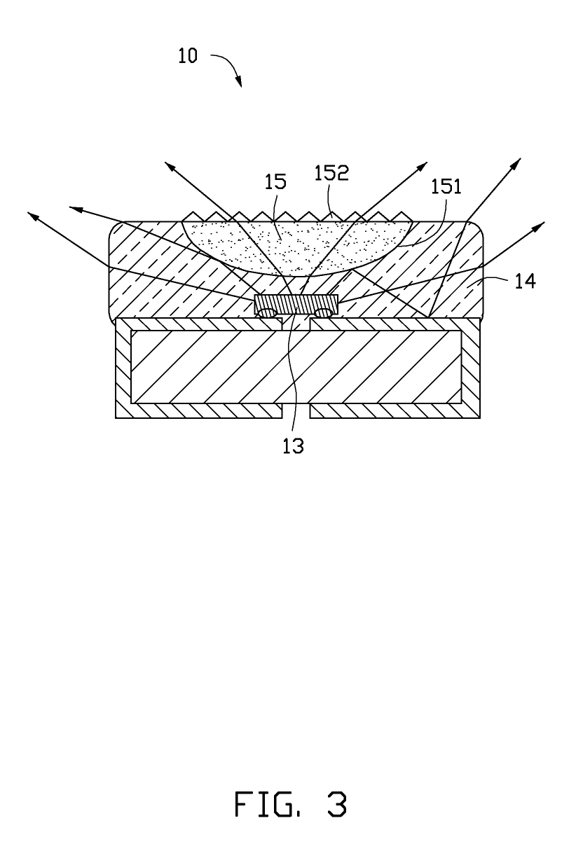

Referring to FIG. 3, the optical element 15 is arranged on the encapsulant 14, and just located above the LED chip 13. In the present embodiment, the optical element 15 is received in the concave portion 142. The optical element 15 includes a light input surface 151 overlaying a surface of the encapsulant 14 in the concave portion 142 and a light output surface 152 opposite to the light input surface 151. The light input surface 151 is convex and protrudes toward the LED chip 13. In the present embodiment, the light input surface 151 is aspheric. The light output surface 152 is rugged, and has a plurality of micro-structures thereon. The optical element 15 is formed of a material, for example, an epoxy which has a second refractive index n₂ . The first refractive index n₁ of the encapsulant 14 is larger than the second refractive index n₂ of the optical element 15. A first part (i.e., peripheral part) of light emitted from a center of the LED chip 13 travels toward the light input surface 151 and is totally reflected by the light input surface 151 to different directions deviating from the center of the LED chip 13; thus, the light outputting angle of the LED device 10 is larger. A second part (i.e., central part) of the light emitted from the LED chip 13 directly travels through the light input surface 151 to an outside of the LED device 10 via the rugged light output surface 151 of the optical element 15. The rugged light output surface 151 and the body of the optical element 15 refract the second part of the light sideways. Accordingly, the light intensity at the center of the light field is decreased, and at the periphery of the light filed in increased. Thus, the LED device 10 can achieve a uniform distribution for the light intensity of the light filed.

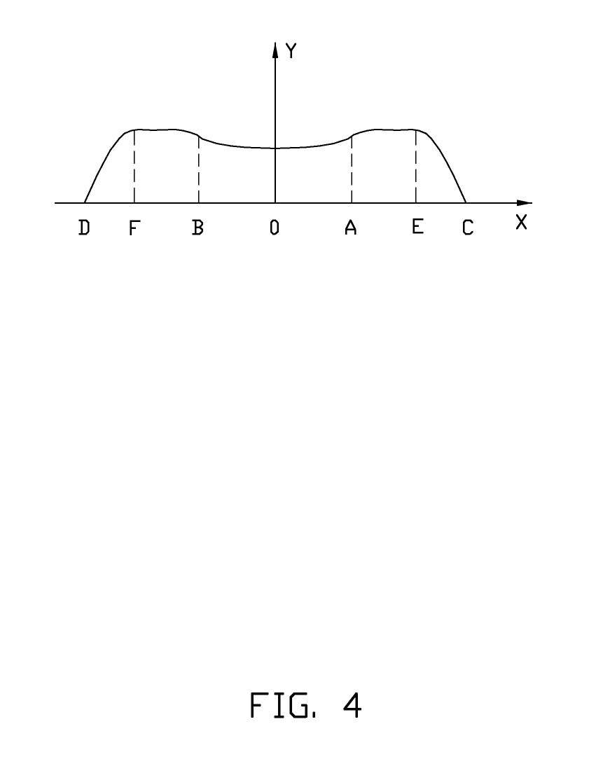

Referring to FIG. 4 also, X-axis represents an illumination angle of the LED device 10 wherein 0 degree means where an optical axis (center) of the LED device 10 is located. Y-axis represents the light intensity of the light filed of the LED device 10.

The center of the LED device 10 is coincidental with the center of the LED chip 13. A and B represent a central illumination range of the LED device 10, and C and D represent a total illumination range of the LED device 10. E and F represent a peripheral illumination range of the LED device 10. It can be seen from FIG. 4 that the light intensity in the central illumination range (A-B) of the LED device 10 is smaller than that within the peripheral illumination range (E-F) and outside the central illumination range (A-B) of the LED device 10. In the present embodiment, A is in an angle between 50 and 60 degrees, B is an angle between −50 and −60 degrees, C is an angle between 80 and 90 degrees, and D is an angle between −80 to −90 degrees. The light intensity achieves a peak value at about 70 or −70 degrees of the light outputting angle (points E and F) deviating from the center of the LED chip 13. It is noted that the light outputting angle of the LED device 10 is the full angle at which the light intensity is half of the peak light intensity. Therefore, the LED device 10 has a light outputting angle much larger than 140 degrees.

Since a first part of light emitted from the center of the LED chip 13 travels toward the light input surface 151 and is totally reflected by the light input surface 151 to different directions deviating from the center of the LED chip 13; thus, the light emitting angle of the LED device 10 is increased. Furthermore, the intensive central light is directed sideways; thus, the distribution of the intensity of the light field is more uniform.

It is to be further understood that even though numerous characteristics and advantages have been set forth in the foregoing description of embodiments, together with details of the structures and functions of the embodiments, the disclosure is illustrative only; and that changes may be made in detail, especially in matters of shape, size, and arrangement of parts within the principles of the disclosure to the full extent indicated by the broad general meaning of the terms in which the appended claims are expressed.

What is claimed is:

1. An LED device comprising:
a substrate;
an LED chip arranged on the substrate;
an encapsulant covering the LED chip; and
an optical element arranged on the encapsulant, the optical element comprising a light input surface adjacent to the encapsulant and a light output surface opposite to the light input surface, the refractive index of the encapsulant being larger than that of the optical element.

2. The LED device of claim 1, wherein the light input surface is convex and protrudes towards the LED chip.

3. The LED device of claim 2, wherein the light input surface is aspheric.

4. The LED device of claim 1, wherein the optical element is just located above the LED chip.

5. The LED device of claim 1, wherein the light output surface is a rugged surface and has a plurality of micro-structures thereon.

6. The LED device of claim 1, further comprising a first electrode and a second electrode extend from a top surface of the substrate to a bottom surface of the substrate, the LED chip being arranged on the first electrode and the second electrode.

7. The LED device of claim 1, wherein an upper surface of the encapsulantis is recessed downwardly to define a concave portion, the optical element being received in the concave portion.

8. An LED device comprising:
a substrate having a top surface;
an LED chip arranged on the top surface of the substrate;
an encapsulant arranged on the top surface of the substrate and covering the LED chip; and
an optical element arranged on the encapsulant, the optical element comprising a light input surface adjacent to the encapsulant and a light output surface opposite to the light input surface, part of light emitted from the LED chip being reflected by the light input surface to different directions, and other part of the light travelling through the light input surface and being refracted by the optical element to an outside of the LED device.

9. The LED device of claim 8, wherein the refractive index of the encapsulant is larger than that of the optical element.

10. The LED device of claim 8, wherein the optical element is just located above the LED chip.

11. The LED device of claim 8, wherein the light input surface is convex and protrudes toward to the LED chip.

12. The LED device of claim 11, wherein an upper surface of the encapsulant is recessed downwardly to define a concave portion in a center thereof, and the light input surface of the optical element overlays a surface the encapsulant in the concave portion.

13. The LED device of claim 11, wherein the light input surface is aspheric.

14. The LED device of claim 8, wherein the light output surface is a rugged and has a plurality of micro-structures thereon.

15. An LED device comprising:
a substrate comprising a top surface and a bottom surface opposite to the top surface;
two electrodes formed on the top surface of the substrate;
an LED chip mounted on the top surface of the substrate and electrically connecting the electrodes;
an encapsulant encapsulating the LED chip, a center of an upper surface of the encaspulant being recessed downwardly to define a concave portion; and
an optical element arranged in the concave portion, the optical element having a light input surface overlaying a surface of the concave portion of the encapsulant and a light output surface opposite to the light input surface, the refractive index of the encapsulant being larger than that of the optical element, the light input surface of the optical element reflecting part of light emitting from the LED chip and through the encapsulant towards different directions deviating from a center of the LED chip.
